(19) United States
(12) Patent Application Publication
(10) Pub. No.: US 2024/0364022 A1
(43) Pub. Date: Oct. 31, 2024

(54) ANTENNA MODULE

(71) Applicant: Murata Manufacturing Co., Ltd., Nagaokakyo-shi (JP)

(72) Inventors: Michiharu YOKOYAMA, Nagaokakyo-shi (JP); Takaya NEMOTO, Nagaokakyo-shi (JP); Hideki UEDA, Nagaokakyo-shi (JP)

(73) Assignee: Murata Manufacturing Co., Ltd., Nagaokakyo-shi (JP)

(21) Appl. No.: 18/768,233

(22) Filed: Jul. 10, 2024

Related U.S. Application Data
(63) Continuation of application No. PCT/JP2022/041396, filed on Nov. 7, 2022.

(30) Foreign Application Priority Data
Jan. 17, 2022 (JP) 2022-005060

(51) Int. Cl. H01Q 21/06; H01Q 1/22

(52) U.S. Cl. CPC H01Q 21/065; H01Q 1/2283; H01Q 21/062

(57) ABSTRACT

A sub-module includes a plurality of electronic components and a first support. Each of the plurality of electronic components includes a plurality of internal terminals. The first support covers and supports the plurality of electronic components to expose the plurality of internal terminals. A first conductive film is disposed on at least a part of the first support. A second support supports the sub-module and supports an antenna. A plurality of external terminals exposed from the second support are connected to the plurality of internal terminals.

### CROSS-REFERENCE TO RELATED APPLICATIONS

This application is a continuation of international application no. PCT/JP2022/041396, filed Nov. 7, 2022, and which claims priority to Japanese application no. 2022-005060, filed Jan. 17, 2022. The entire contents of both prior applications are hereby incorporated by reference.

### BACKGROUND

### 1. Description of the Related Art

A technique exists for mounting a plurality of integrated circuit devices on an interposer and sealing the devices with resin. With the need for reduction in size and reduction in height of portable mobile communication terminals, it is desired to reduce the size and height of components built in the communication terminals, in particular, components including antennas.

### SUMMARY

In modules obtained by mounting a plurality of devices on an interposer and sealing the devices with resin, the thickness of the interposer becomes a bottleneck, and it is difficult to reduce the height. In addition, when a high frequency circuit and an antenna are mounted on a common interposer, electromagnetic interference is likely to occur between the high frequency circuit and the antenna. Therefore, the present disclosure provides, at least in part, an antenna module that can be reduced in height and ensure isolation between a high frequency circuit and an antenna.

According to an aspect of the present disclosure, an antenna module includes a sub-module including a plurality of electronic components each including a plurality of internal terminals. A first support covers and supports the plurality of electronic components to expose the plurality of internal terminals, and a first conductive film is disposed on at least a part of the first support. The antenna module also includes least one antenna, a second support that supports the sub-module and supports the antenna, and a plurality of external terminals that are connected to the plurality of internal terminals and are exposed from the second support member.

The electronic components are connected to the external terminal with the internal terminals interposed therebetween, and the external terminals are used as terminals for mounting the electronic components on the module substrate or the like. Since the substrate is not disposed between the electronic components and the external terminals, the height of the antenna module can be reduced. Since the first conductive film functions as an electromagnetic shielding film, the isolation between the circuit in the sub-module and the antenna can be improved.

### BRIEF DESCRIPTION OF THE DRAWINGS

FIG. 1 is a cross-sectional view of an antenna module according to a first exemplary embodiment;

FIG. 2A is a cross-sectional view of a sub-module at a manufacturing stage;

FIG. 2B is another cross-sectional view of the sub-module at a manufacturing stage;

FIG. 2C is a further cross-sectional view of the sub-module at a manufacturing stage;

FIG. 2D is a still further cross-sectional view of the sub-module at a manufacturing stage;

FIG. 2E is a cross-sectional view of the sub-module;

FIG. 3A is a cross-sectional view of the antenna module at the manufacturing stage;

FIG. 3B is another cross-sectional view of the antenna module at the manufacturing stage;

FIG. 3C is a further view of the antenna module at the manufacturing stage;

FIG. 4 is a cross-sectional view of an antenna module according to a second exemplary embodiment;

FIG. 5 is a schematic view illustrating a positional relationship in plan view of a conductor pattern, a sub-module, and a plurality of antennas disposed on a second surface of a second support member of an antenna module according to a third exemplary embodiment;

FIG. 6 is a cross-sectional view of an antenna module according to a fourth exemplary embodiment;

FIG. 7 is a cross-sectional view of an antenna module according to a fifth exemplary embodiment;

FIG. 8 is a cross-sectional view of an antenna module according to a sixth exemplary embodiment;

FIG. 9A is a cross-sectional view of an antenna module according to a seventh exemplary embodiment;

FIG. 9B is a schematic view illustrating a planar positional relationship of a plurality of components of the antenna module according to the seventh exemplary embodiment;

FIG. 10 is a cross-sectional view of an antenna module according to a modification example of a seventh exemplary embodiment;

FIG. 11 is a schematic view illustrating a planar positional relationship of a plurality of components of an antenna module according to another modification example of the seventh exemplary embodiment;

FIG. 12A is a cross-sectional view an antenna module according to an eighth exemplary embodiment;

FIG. 12B is a side view of the antenna module according to the eighth exemplary embodiment;

FIG. 12C is a bottom view of the antenna module according to the eighth exemplary embodiment;

FIG. 13 is a side view of an antenna module according to a modification example of the eighth exemplary embodiment;

FIG. 14 is a cross-sectional view of an antenna module according to a ninth exemplary embodiment;

FIG. 15 is a cross-sectional view of an antenna module according to a tenth exemplary embodiment;

FIG. 16 is a schematic view illustrating a planar positional relationship of a plurality of components of an antenna module according to an eleventh exemplary embodiment;

FIG. 17 is a cross-sectional view of the antenna module according to the eleventh exemplary embodiment;

FIG. 18 is a cross-sectional view of an antenna module according to a twelfth exemplary embodiment;

FIG. 19 is a schematic view illustrating a planar disposition of a plurality of components of an antenna module according to a modification example of the twelfth exemplary embodiment;

FIG. 20 is a cross-sectional view of an antenna module according to a thirteenth exemplary embodiment;

FIG. 21A is a cross-sectional view of an antenna module according to a fourteenth exemplary embodiment;

FIG. 21B is a cross-sectional view of an antenna module according to a modification example of the fourteenth exemplary embodiment;

FIG. 22A is a cross-sectional view of an antenna module according to another modification example of the fourteenth exemplary embodiment; and

FIG. 22B is another cross-sectional view of the antenna module according to a further modification example of the fourteenth exemplary embodiment.

### DESCRIPTION OF THE EXEMPLARY EMBODIMENTS

### First Exemplary Embodiment

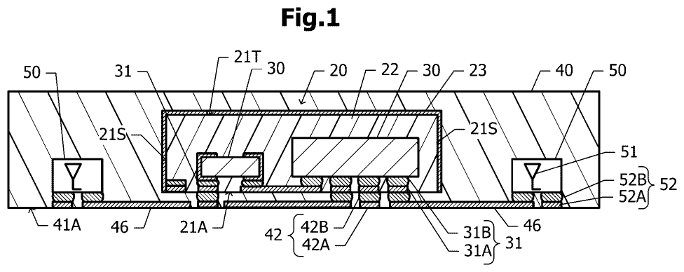

An antenna module according to a first exemplary embodiment will be described with reference to the drawings from FIGS. 1 to 3C.

FIG. 1 is a cross-sectional view of the antenna module according to the first embodiment. FIG. 1 does not illustrate a specific cross-section obtained by cutting the antenna module along a plane, but illustrates a cross-sectional structure, obtained by cutting the antenna module at various points, as one cross-section. In addition, the elements illustrated as being isolated into two parts in FIG. 1 may also be connected to each other at a point other than the cross-section appearing in FIG. 1.

The antenna module according to the first exemplary embodiment includes a sub-module 20 and a plurality of antennas 50. Hereinafter, the configuration of the sub-module 20 will be described. The sub-module 20 includes a plurality of electronic components 30 and a first support member 22 made of a resin, which covers and supports the plurality of electronic components 30.

Each of the electronic components 30 includes a plurality of internal terminals 31, and the plurality of internal terminals 31 are exposed on one surface of the sub-module 20. The surface at which the plurality of internal terminals 31 are exposed is referred to as a first surface 21A. A substantially flat first surface 21A is configured by one surface of the first support member 22 and the exposed surfaces of the plurality of internal terminals 31. The first support member 22 includes a top surface 21T that faces in a direction opposite to the first surface 21A, and a side surface 21S that connects the first surface 21A to the top surface 21T.

The electronic component 30 is, for example, an individual component such as a semiconductor integrated circuit, a surface-mounted inductor, or a capacitor. The sub-module 20 has, for example, a function of an RF front end. The RF front end performs, for example, up-conversion from an intermediate frequency signal to a high frequency signal, down-conversion from the high frequency signal to the intermediate frequency signal, amplification of the high frequency signal, and the like.

Each internal terminal 31 includes, for example, two layers of a first electrode 31A made of Cu and a solder 31B. The first electrode 31A is exposed at the first surface 21A of the sub-module 20. The top surface 21T and the side surface 21S of the first support member 22 are covered with a first conductive film 23. The first conductive film 23 functions as an electromagnetic shielding film. The first conductive film 23 may be a full surface film (solid film) provided on the entire region of a specific range, or a patterned film having an electromagnetic shielding function, for example, a meshed film or a striped film. At least one of the plurality of first electrodes 31A exposed at the first surface 21A is exposed at the side surface 21S of the first support member 22 and is electrically connected to the first conductive film 23. The first conductive film 23 is connected to a ground potential via the first electrodes 31A exposed at the side surface 21S of the first support member 22.

Each of the plurality of antennas 50 is configured with an antenna component including a radiating element 51 and an antenna terminal 52. In FIG. 1, a radiating element 51 is represented by a circuit symbol. As the radiating element 51, for example, a radiating element such as a patch antenna or a dipole antenna is used.

The sub-module 20 and the plurality of antennas 50 are covered with and supported by a second support member 40 made of resin. The second support member 40 is in contact with the first surface 21A of the sub-module 20 and includes a second surface 41A that faces in the same direction as the first surface 21A. Each of a plurality of external terminals 42 is exposed at the second surface 41A, and is connected to the internal terminal 31 of the electronic component 30 in the second support member 40. The internal terminal 31 and the external terminal 42 that are connected to each other are disposed at the same position in plan view. The external terminal 42 includes a second electrode 42A exposed at the second surface 41A and a solder 42B connected to the internal terminal 31.

Each of the plurality of antenna terminals 52 includes a third electrode 52A, exposed at the second surface 41A, and a solder 52B. The third electrode 52A is connected to the radiating element 51 with the solder 52B interposed therebetween. One antenna terminal 52 of the plurality of antenna terminals 52 of the antenna 50 is connected to one external terminal 42 of the plurality of external terminals 42 of the sub-module 20 with a first feed line 46, disposed on the second surface 41A, interposed therebetween.

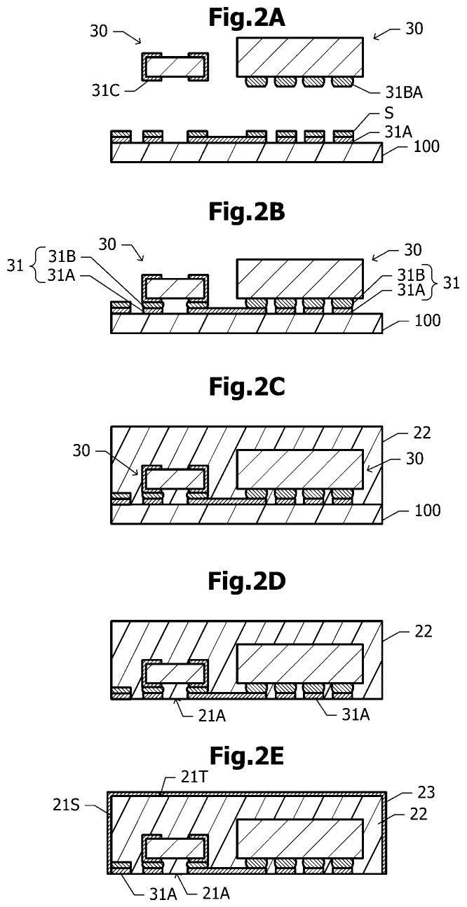

Next, a method for manufacturing the sub-module 20 will be described with reference to the drawings from FIGS. 2A to 2E. The drawings from FIGS. 2A to 2D are cross-sectional views of the sub-module 20 at a manufacturing stage, and FIG. 2E is a cross-sectional view of the sub-module 20.

As illustrated in FIG. 2A, a plurality of electronic components 30 and a temporary substrate 100 are prepared. A printed circuit board can be used as the temporary substrate 100. The plurality of first electrodes 31A are disposed on the surface of the temporary substrate 100, and a solder S is placed on the first electrodes. At the stage illustrated in FIG. 2A, the sub-module 20 is not divided into individual pieces, but FIG. 2A illustrates only a region corresponding to one sub-module 20. The electronic component 30, such as a semiconductor integrated circuit, includes a plurality of solder balls 31BA for mounting. The electronic component 30, such as a surface-mounted individual component, includes a mounting electrode 31C.

As illustrated in FIG. 2B, the solder balls 31BA or the electrode 31C of the electronic component 30 are placed on the solder S of the temporary substrate 100 and subjected to reflow treatment. Accordingly, the electronic component 30 is fixed to the temporary substrate 100. By the reflow treatment, the internal terminal 31 composed of the solder 31B, obtained by integrating the solder ball 31BA (FIG. 2A) and the solder S (FIG. 2A), and the first electrode 31A is formed. In the electronic component 30 provided with the electrode 31C, the internal terminal 31 is formed by the solder 31B, formed by melting and solidifying the solder S, and the first electrode 31A.

As illustrated in FIG. 2C, the first support member 22 made of sealing resin is formed by covering the plurality of electronic components 30 with the sealing resin. For example, a transfer molding method, a compression molding method, or the like can be used to form the first support member 22. As the first support member 22, for example, epoxy resin is used.

As illustrated in FIG. 2D, the temporary substrate 100 (FIG. 2C) is ground to expose the plurality of first electrodes 31A. The first support member 22 is exposed in the region where the first electrode 31A is not disposed. Accordingly, the flat first surface 21A including the surface of the first support member 22 and the surfaces of the plurality of first electrodes 31A is exposed. After grinding, division into individual sub-modules 20 is made.

As illustrated in FIG. 2E, the first conductive film 23 is formed on the top surface 21T and the side surface 21S of the first support member 22. For example, a metal such as Cu, Ag, and Ni is used as the first conductive film 23. The first conductive film 23 may have a laminated structure of a plurality of metals. For example, sputtering can be used to form the first conductive film 23. The first conductive film 23 is connected to the first electrode 31A exposed at the side surface 21S.

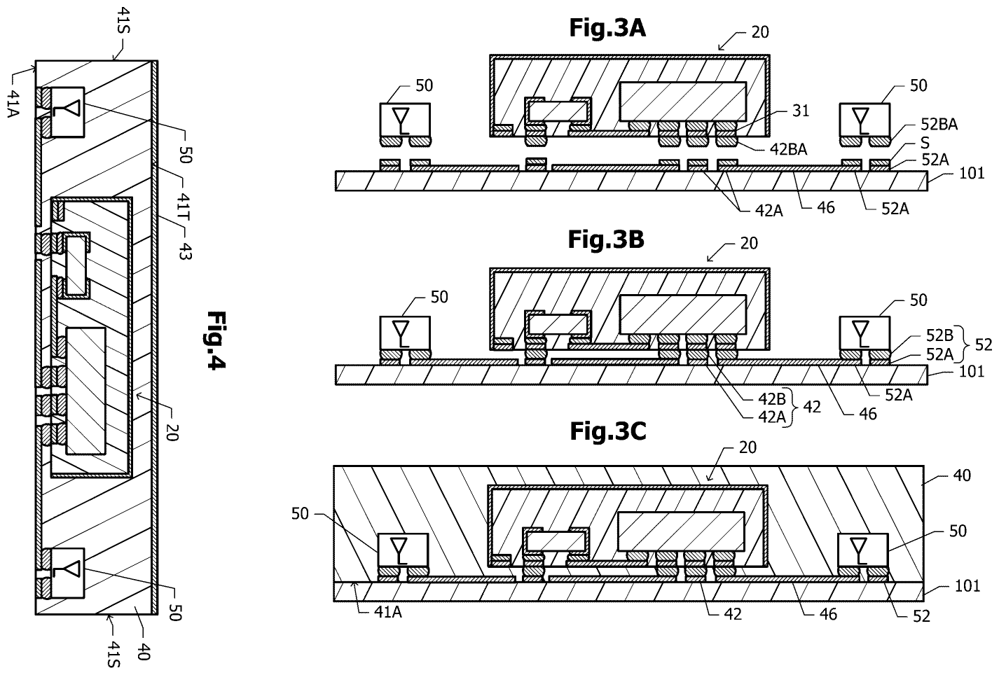

Next, a method for manufacturing the antenna module according to the first embodiment will be described with reference to the drawings from FIGS. 3A to 3C. FIGS. 3A, 3B, and 3C are cross-sectional views at the manufacturing stage of the antenna module.

As illustrated in FIG. 3A, a temporary substrate 101, the sub-module 20, and the plurality of antennas 50 are prepared. The plurality of second electrodes 42A, the plurality of third electrodes 52A, and the plurality of first feed lines 46 are disposed on the surface of the temporary substrate 101. The first feed line 46 is continuous with the second electrode 42A and the third electrode 52A. The solder S is placed on the second electrode 42A and the third electrode 52A. A printed circuit board can be used as the temporary substrate 101. A solder ball 42BA is placed on the surface of the sub-module 20 at which the internal terminal 31 is exposed. A solder ball 52BA is placed on the terminal of the antenna 50.

As illustrated in FIG. 3B, the sub-module 20 and the antennas 50 are fixed to the temporary substrate 101 by placing the sub-module 20 and the antennas 50 on the temporary substrate 101 to perform the reflow treatment. The external terminal 42 is formed by the solder 42B, obtained by integrating the solder ball 42BA and the solder S, and the second electrode 42A. The antenna terminal 52 is formed by the solder 52B, obtained by integrating the solder ball 52BA and the solder S, and the third electrode 52A. The antennas 50 and the sub-module 20 are connected to each other by the first feed line 46.

As illustrated in FIG. 3C, the second support member 40 is formed by sealing the sub-module 20 and the antennas 50 with sealing resin. For example, a transfer molding method, a compression molding method, or the like can be used to form the second support member 40. As the second support member 40, for example, epoxy resin is used.

After the second support member 40 is formed, the temporary substrate 101 is ground to expose the external terminal 42, the antenna terminal 52, the first feed line 46, and the second support member 40. A substantially flat second surface 41A is configured by the surface of the external terminal 42, the surface of the antenna terminal 52, the surface of the first feed line 46, and the surface of the second support member 40. Finally, the antenna module illustrated in FIG. 1 is completed by division into each antenna module.

Next, effects of the first exemplary embodiment will be described.

In the first exemplary embodiment, a substrate, such as an interposer, is not disposed in the space between the electronic components 30 (FIG. 1) and the second surface 41A. In other words, the electronic components 30 according to the first exemplary embodiment can be mounted on a module substrate or the like without using an interposer. Therefore, it is possible to reduce the height of the antenna module as compared with a configuration in which a substrate, such as an interposer, is disposed. In the first exemplary embodiment, the second support member 40 is disposed on the top surface 21T of the first support member 22. However, in a case where the sub-module 20 can be supported with only the first surface 21A and the side surface 21S, the second support member 40 does not need to be disposed on the top surface 21T of the sub-module 20. By employing this configuration, it is possible to further reduce the height.

Since the top surface 21T and the side surface 21S of the first support member 22 of the sub-module 20 are covered with the first conductive film 23 (FIG. 1) that functions as an electromagnetic shielding film, the isolation between the high frequency circuit in the sub-module 20 and the antenna 50 can be ensured. In addition, in a case where another high frequency circuit component is supported by the second support member 40, it is possible to ensure the isolation between the high frequency circuit in the sub-module 20 and the other high frequency circuit component.

In addition, as an example, when the sub-module 20 is disposed between the two antennas 50 in plan view, the isolation between the two antennas 50 can be improved.

In the first exemplary embodiment, the entire surfaces of the side surface 21S and the top surface 21T of the first support member 22 are covered with the first conductive film 23, but only a partial region may be covered. For example, the first conductive film 23 may be disposed between the components to be electromagnetically shielded, in a region where leakage of high frequency noise is to be suppressed, or the like.

Since the sub-module 20 and the antenna 50 are connected to each other by the first feed line 46 disposed on the second surface 41A, wiring lines can be terminated in the antenna module. In a case where the antenna module is mounted on another substrate, for example, a module substrate or the like, the number of wiring lines to be formed on the other substrate can be reduced. Accordingly, the thickness of the module substrate and the like can be reduced.

Since the plurality of antennas 50 are covered with the second support member 40 made of resin, the bandwidth of the antenna 50 can be increased.

### Second Exemplary Embodiment

Next, an antenna module according to a second exemplary embodiment will be described with reference to FIG. 4. Hereinafter, the description of the configuration in common with the antenna module according to the first exemplary embodiment described with reference to the drawings of FIGS. 1 to 3C will be omitted.

FIG. 4 is a cross-sectional view of the antenna module according to the second exemplary embodiment. The second support member 40 includes a top surface 41T that faces in the direction opposite to the second surface 41A, and a side surface 41S that connects the second surface 41A to the top surface 41T. In the first exemplary embodiment (FIG. 1), a conductive film (in particular, a conductive film having a shielding function) is not disposed in the second support member 40. On the other hand, in the second exemplary embodiment, the second conductive film 43 is disposed on the top surface 41T of the second support member 40. No conductive film is disposed on the side surface 41S. The second conductive film 43 can be formed on the top surface of the second support member 40 by sputtering, for example, before the antenna module is divided into individual pieces. For example, metals such as Cu, Ag, and Ni are used as the second conductive film 43. When the top surface 41T is viewed in plan, the plurality of antennas 50 are included in the second conductive film 43.

Next, effects of the second exemplary embodiment will be described.

Similarly to the first exemplary embodiment, in the second exemplary embodiment, it is possible to reduce the height and increase the bandwidth, and ensure the isolation between the high frequency circuit in the sub-module 20 and the antenna 50. Furthermore, in the second exemplary embodiment, the isolation between the antennas 50 can be further improved since the second conductive film 43 functions as an electromagnetic shielding film.

Furthermore, the directivity of the antenna 50 can be controlled by the second conductive film 43. For example, a main beam can be directed in the direction in which the side surface 41S, on which the conductive film is not disposed, faces.

### Third Exemplary Embodiment

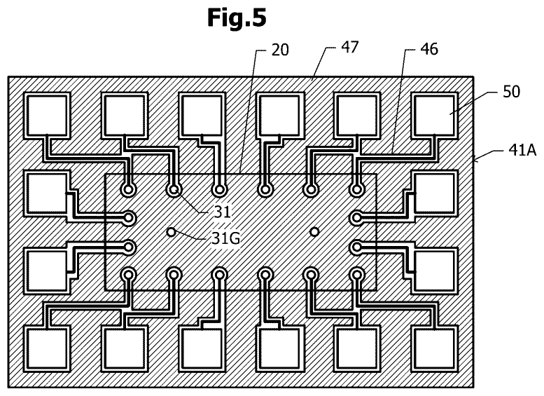

Next, an antenna module according to a third exemplary embodiment will be described with reference to FIG. 5. Hereinafter, the description of the configuration in common with the antenna module according to the second exemplary embodiment illustrated in FIG. 4 will be omitted.

FIG. 5 is a schematic view illustrating a positional relationship in plan view of a conductor pattern, the sub-module 20, and the plurality of antennas 50 disposed on the second surface 41A of the second support member 40 (FIG. 4) of the antenna module according to the third exemplary embodiment. The plurality of antennas 50 are disposed to surround the sub-module 20. Each of the plurality of internal terminals 31 of the sub-module 20 is connected to the antenna 50 with the first feed line 46 interposed therebetween. A ground plane 47 is disposed on the second surface 41A so as not to overlap the first feed line 46. In FIG. 5, the ground plane 47 is hatched. The ground plane 47 is connected to a ground terminal 31G in the plurality of internal terminals 31 of the sub-module 20.

Next, effects of the third exemplary embodiment will be described.

Similarly to the first exemplary embodiment, also in the third exemplary embodiment, it is possible to reduce the height and increase the bandwidth, and ensure the isolation between the high frequency circuit in the sub-module 20 and the antenna 50. Furthermore, in the third exemplary embodiment, in addition to the second conductive film 43 (FIG. 4) disposed on the top surface 41T of the second support member 40, the ground plane 47 disposed on the second surface 41A also functions as an electromagnetic shielding film. Therefore, the directivity of the antenna 50 can be controlled within a narrower range.

### Fourth Exemplary Embodiment

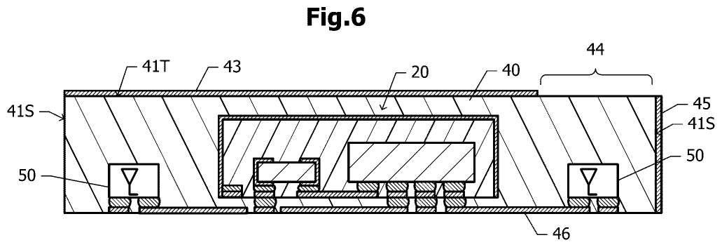

Next, an antenna module according to a fourth exemplary embodiment will be described with reference to FIG. 6. Hereinafter, the description of the configuration in common with the antenna module according to the second exemplary embodiment illustrated in FIG. 4 will be omitted.

FIG. 6 is a cross-sectional view of the antenna module according to the fourth exemplary embodiment. In the second exemplary embodiment (FIG. 4), the second conductive film 43 is disposed on the entire region of the top surface 41T of the second support member 40. On the other hand, in the fourth exemplary embodiment, the second conductive film 43 is disposed in a partial region of the top surface 41T. A region of the top surface 41T where the second conductive film 43 is not disposed (hereinafter, referred to as an opening 44) and at least one antenna 50 of the plurality of antennas 50 overlap each other in plan view. In other words, the opening 44 is provided in the second conductive film 43, and a partial region of the top surface 41T of the second support member 40 is exposed. A third conductive film 45 is disposed in a region of the side surface 41S in the vicinity of the antenna 50 that overlaps the opening 44 in plan view. For example, the antenna 50 that overlaps the opening 44 in plan view is in a positional relationship sandwiched between the third conductive film 45 and the sub-module 20. The third conductive film 45 may be continuous with the second conductive film 43 in a region other than the cross-section appearing in FIG. 6.

Next, effects of the fourth exemplary embodiment will be described.

Similarly to the first exemplary embodiment, also in the fourth exemplary embodiment, it is possible to reduce the height and increase the bandwidth, and ensure the isolation between the high frequency circuit in the sub-module 20 and the antenna 50. Furthermore, in the fourth exemplary embodiment, the second conductive film 43 and the third conductive film 45 function as electromagnetic shielding films, so that the directivity of the antenna 50 that overlaps the opening 44 in plan view can be controlled. For example, radio waves radiated from the antenna 50 that overlaps the opening 44 in plan view are radiated to the outside through the opening 44. Therefore, the main beam can be directed upward (in the direction in which the top surface 41T faces).

Similarly to the second exemplary embodiment, for the antenna 50 that overlaps the second conductive film 43 in plan view, the main beam can be directed in the direction in which the side surface 41S faces.

### Fifth Exemplary Embodiment

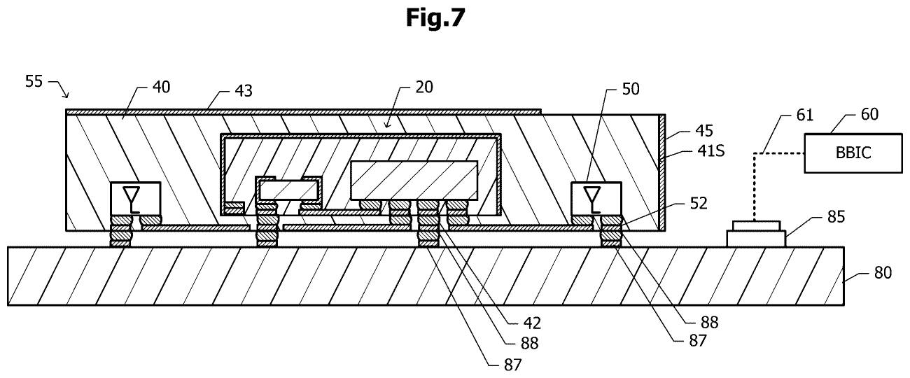

Next, an antenna module according to a fifth exemplary embodiment will be described with reference to FIG. 7. Hereinafter, the description of the configuration in common with the antenna module according to the fourth exemplary embodiment illustrated in FIG. 6 will be omitted.

FIG. 7 is a cross-sectional view of the antenna module according to the fifth exemplary embodiment. The antenna module according to the fifth embodiment includes an antenna built-in RF front end portion 55 and a module substrate 80 on which the antenna built-in RF front end portion 55 is mounted. As the antenna built-in RF front end portion 55, the antenna module (FIG. 6) according to the fourth exemplary embodiment is used. A plurality of lands 87 are provided on one surface of the module substrate 80. The antenna built-in RF front end portion 55 is mounted on the module substrate 80 by fixing the external terminal 42 and the antenna terminal 52 of the antenna built-in RF front end portion 55 to the lands 87 by the solder 88.

A high frequency connector 85 is mounted on the module substrate 80. The connector 85 is connected to a baseband integrated circuit component 60, for example, with a coaxial cable 61 interposed therebetween. Furthermore, the connector 85 is connected to the sub-module 20 of the antenna built-in RF front end portion 55 with wiring lines (not illustrated) in the module substrate 80 interposed therebetween. An intermediate frequency signal and a control signal are transmitted between the sub-module 20 and the baseband integrated circuit component 60 through the coaxial cable. The third conductive film 45 is disposed in a region of the side surface 41S of the second support member 40, the region facing the connector 85 side. The third conductive film 45 functions as an electromagnetic shielding film.

Next, effects of the fifth embodiment will be described.

Similarly to the first exemplary embodiment, also in the fifth exemplary embodiment, it is possible to reduce the height and increase the bandwidth, and ensure the isolation between the high frequency circuit in the sub-module 20 and the antenna 50. Furthermore, in the fifth embodiment, the third conductive film 45 functioning as an electromagnetic shielding film is disposed between the antenna built-in RF front end portion 55, supported by the second support member 40, and the connector 85. Therefore, the isolation between the connector 85 and the antenna built-in RF front end portion 55 including the sub-module 20 and the antenna 50 can be ensured.

### Sixth Exemplary Embodiment

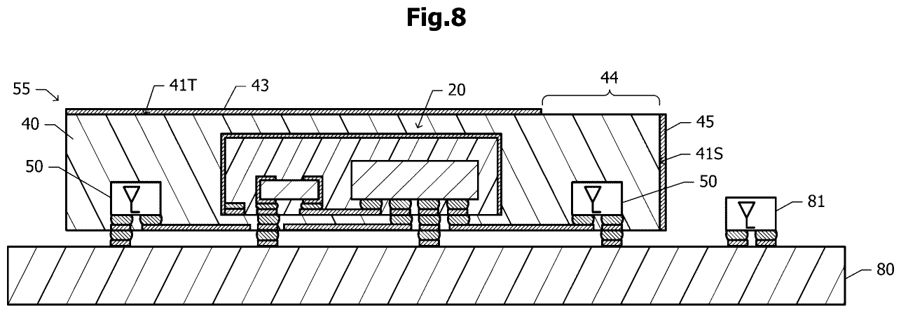

Next, an antenna module according to a sixth exemplary embodiment will be described with reference to FIG. 8. Hereinafter, the description of the configuration in common with the antenna module according to the fifth exemplary embodiment illustrated in FIG. 7 will be omitted.

FIG. 8 is a cross-sectional view of the antenna module according to the sixth exemplary embodiment. In the fifth exemplary embodiment (FIG. 7), the antenna built-in RF front end portion 55 and the connector 85 are mounted on the module substrate 80. In the sixth exemplary embodiment, an external antenna component 81 is further mounted on the module substrate 80. The connector 85 (FIG. 7) does not appear in the cross-section illustrated in FIG. 8.

The third conductive film 45 is disposed in a region of the side surface 41S of the second support member 40 in the vicinity of the antenna 50 that overlaps the opening 44 of the second conductive film 43 in plan view. The antenna built-in RF front end portion 55 and the external antenna component 81 are disposed in such a positional relationship that the side surface 41S, on which the third conductive film 45 is disposed, faces the external antenna component 81. When viewed in plan, the positional relationship is that the third conductive film 45 is disposed between the antenna 50, which overlaps the opening 44 of the second conductive film 43, and the external antenna component 81.

Next, effects of the sixth exemplary embodiment will be described.

Similarly to the first exemplary embodiment, also in the sixth exemplary embodiment, it is possible to reduce the height and increase the bandwidth, and ensure the isolation between the high frequency circuit in the sub-module 20 and the antenna 50. Furthermore, in the sixth exemplary embodiment, the third conductive film 45 functioning as an electromagnetic shielding film is disposed between the antenna built-in RF front end portion 55 and the external antenna component 81. Therefore, the isolation between the antenna built-in RF front end portion 55 and the external antenna component 81 can be ensured.

The third conductive film 45 functions as a reflector, and the main beam of the external antenna component 81 is directed in a direction normal to the side surface 41S on which the third conductive film 45 is disposed. In this way, the directivity of the external antenna component 81 can be controlled.

### Seventh Exemplary Embodiment

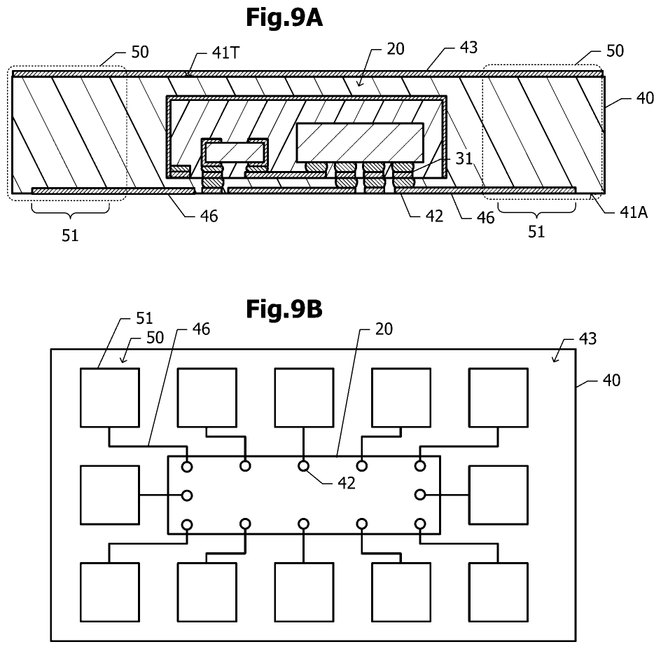

Next, an antenna module according to a seventh exemplary embodiment will be described with reference to FIGS. 9A and 9B. Hereinafter, the description of the configuration in common with the antenna module according to the first exemplary embodiment described with reference to the drawings of FIGS. 1 to 3C will be omitted.

FIG. 9A is a cross-sectional view of an antenna module according to a seventh exemplary embodiment, and FIG. 9B is a schematic view illustrating a planar positional relationship of a plurality of components of the antenna module according to the seventh exemplary embodiment. In the first exemplary embodiment (FIG. 1), the antenna component including the radiating element 51 and the antenna terminal 52 is used as the antenna 50, and the antenna component is embedded in and supported by the second support member 40. On the other hand, in the seventh exemplary embodiment, the radiating element 51 of the antenna 50 is configured with a metal pattern disposed on the second surface 41A of the second support member 40. The radiating element 51 is connected to the internal terminal 31 of the sub-module 20 with the first feed line 46 and the external terminal 42, disposed on the second surface 41A, interposed therebetween.

The second conductive film 43 is disposed on the entire region of the top surface 41T of the second support member 40. The second conductive film 43 includes a plurality of radiating elements 51 in plan view. The second conductive film 43 is connected to the ground potential. The antenna 50 that operates as a patch antenna is configured by each of the plurality of radiating elements 51 and the second conductive film 43. Radio waves are radiated from each of the radiating elements 51 in the direction in which the second surface 41A of the second support member 40 faces.

Next, effects of the seventh exemplary embodiment will be described.

Similarly to the first exemplary embodiment, in the seventh exemplary embodiment, the height of the antenna module can be reduced. Furthermore, the isolation between the high frequency circuit in the sub-module 20 and the radiating element 51 can be ensured. In addition, in the seventh exemplary embodiment, since the radiating element 51 is configured with the metal pattern disposed on the second surface 41A of the second support member 40, the number of components can be reduced as compared with a configuration in which the antenna component is embedded in the second support member 40 for support.

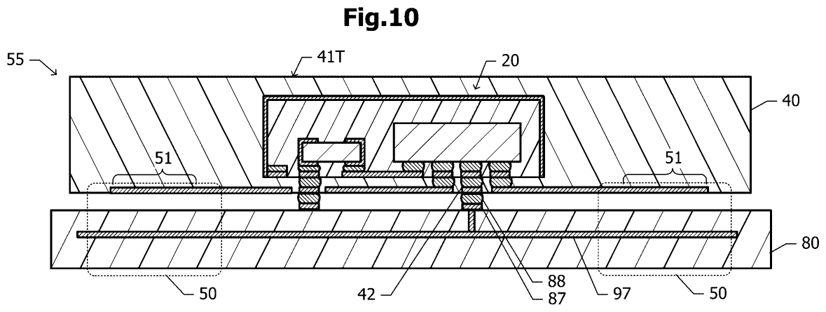

Next, an antenna module according to a modification example of the seventh exemplary embodiment will be described with reference to FIG. 10. FIG. 10 is a cross-sectional view of the antenna module according to the modification example of the seventh exemplary embodiment. The antenna module according to the present modification example includes the antenna built-in RF front end portion 55 and the module substrate 80 on which the antenna built-in RF front end portion 55 is mounted. The antenna built-in RF front end portion 55 has the same configuration as that obtained by removing the second conductive film 43 from the antenna module according to the seventh exemplary embodiment (FIG. 9A).

A ground plane 97 is disposed in the module substrate 80. The ground plane 97 is connected to a terminal to which a ground potential is applied, among the external terminals 42 of the antenna built-in RF front end portion 55, with the land 87 and the solder 88 interposed therebetween. The plurality of radiating elements 51 are included in the ground plane 97 in plan view. The antenna 50 that operates as a patch antenna is configured by the radiating element 51 and the ground plane 97.

In the modification example illustrated in FIG. 10, radio waves are radiated from each of the radiating elements 51 in the direction in which the top surface 41T of the second support member 40 faces.

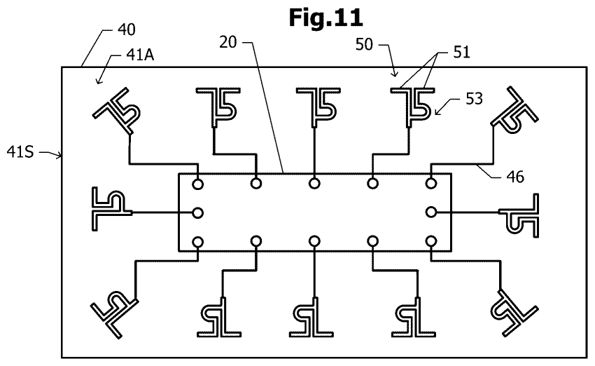

Next, an antenna module according to another modification example of the seventh exemplary embodiment will be described with reference to FIG. 11. FIG. 11 is a schematic view illustrating a planar positional relationship of a plurality of components of the antenna module according to the other modification example of the seventh exemplary embodiment.

In the seventh exemplary embodiment (FIG. 9A), the antenna 50 provided on the second support member 40 is a patch antenna. On the other hand, in the present modification example, the antenna 50 is a dipole antenna. The radiating elements 51 (two elements) of the dipole antenna and a balun 53 are configured with a metal pattern disposed on the second surface 41A of the second support member 40. The radiating elements 51 are connected to the sub-module 20 with the balun 53 and the first feed line 46 interposed therebetween. A differential line may be used as the first feed line 46, and the differential line may be connected to the radiating elements 51 (two elements) of the dipole antenna without using the balun 53.

As in the modification example illustrated in FIG. 11, the dipole antenna may be used as the antenna 50. In this case, radio waves can be radiated in the direction in which the side surface 41S of the second support member 40 faces.

### Eighth Exemplary Embodiment

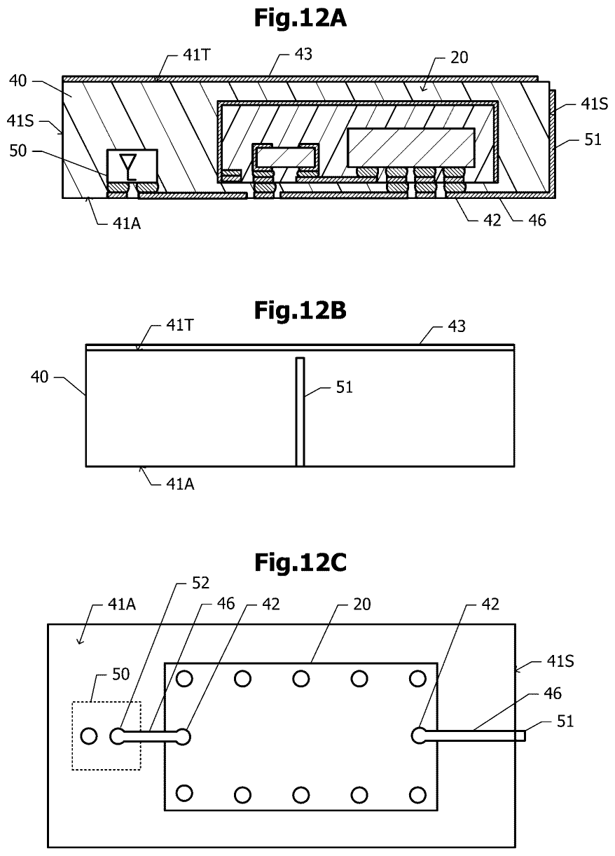

Next, an antenna module according to an eighth exemplary embodiment will be described with reference to FIGS. 12A, 12B, and 12C. Hereinafter, the description of the configuration in common with the antenna module according to the first exemplary embodiment described with reference to the drawings of FIGS. 1 to 3C will be omitted.

FIGS. 12A, 12B, and 12C are a cross-sectional view, a side view, and a bottom view of the antenna module according to the eighth exemplary embodiment, respectively. In the first exemplary embodiment (FIG. 1), the plurality of antennas 50 are embedded in and supported by the second support member 40. The eighth exemplary embodiment includes a radiating element 51 made of a metal pattern disposed on the side surface 41S of the second support member 40, in addition to the antenna 50 embedded in the second support member 40.

The radiating element 51 is configured with a straight metal pattern extending in the height direction from the second surface 41A toward the top surface 41T, and operates as a monopole antenna. The radiating element 51 can be formed by, for example, partial sputtering or the like. The end portion of the radiating element 51 on the second surface 41A side is connected to the external terminal 42 of the sub-module 20 with the first feed line 46 interposed therebetween. An L-shaped monopole antenna may be configured by the first feed line 46 and the radiating element 51.

Next, effects of the eighth exemplary embodiment will be described.

Similarly to the first exemplary embodiment, also in the eighth exemplary embodiment, it is possible to reduce the height and increase the bandwidth, and ensure the isolation between the high frequency circuit in the sub-module 20 and the antenna 50. By configuring some of the plurality of antennas 50 as the metal pattern provided on the side surface 41S of the second support member 40, the number of components can be reduced. In addition, the radiating element 51 provided on the side surface 41S of the second support member 40 can radiate radio waves in the direction in which the side surface 41S faces.

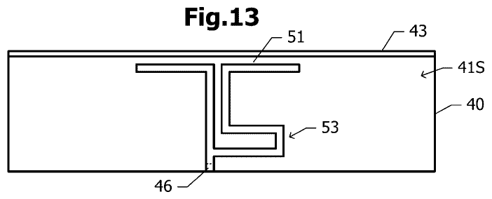

Next, an antenna module according to a modification example of the eighth exemplary embodiment will be described with reference to FIG. 13. FIG. 13 is a side view of the antenna module according to the modification example of the eighth exemplary embodiment. In the eighth exemplary embodiment (FIG. 12B), the radiating element 51 disposed on the side surface 41S of the second support member 40 constitutes a monopole antenna. On the other hand, in the present modification example, the radiating element 51 constitutes a dipole antenna. The radiating element 51 constituting the dipole antenna is connected to the first feed line 46 with the balun 53 interposed therebetween. A differential line may be used as the first feed line 46, and the differential line may be connected to the radiating elements 51 (two elements) of the dipole antenna without using the balun 53. As in the present modification example, it is also possible to dispose the dipole antenna on the side surface 41S of the second support member 40.

### Ninth Exemplary Embodiment

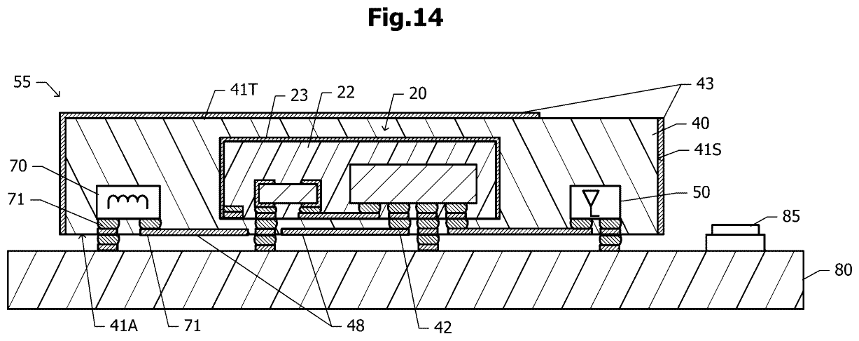

Next, an antenna module according to a ninth exemplary embodiment will be described with reference to FIG. 14. Hereinafter, the description of the configuration in common with the antenna module (FIG. 8) according to the sixth exemplary embodiment will be omitted.

FIG. 14 is a cross-sectional view of the antenna module according to the ninth exemplary embodiment. In the sixth exemplary embodiment (FIG. 8), the antenna built-in RF front end portion 55 includes the sub-module 20 and the plurality of antennas 50. In the antenna module according to the ninth exemplary embodiment, the antenna built-in RF front end portion 55 further includes a surface-mounted chip component 70. In the sixth embodiment (FIG. 8), the external antenna component 81 is mounted on the module substrate 80. However, in the ninth exemplary embodiment, a connector 85 for high frequency signals is mounted instead of the external antenna component 81 or in addition to the external antenna component 81.

The chip component 70 included in the antenna built-in RF front end portion 55 is, for example, a chip inductor. FIG. 14 illustrates an example in which the chip component 70 is a chip inductor, but the chip component 70 is not limited to the chip inductor. For example, as an example of the chip component 70, a surface-mounted ferrite bead, a surface-mounted bypass capacitor, and the like may be used in addition to the chip inductor. The chip component 70 includes a plurality of electrode terminals 71. The plurality of electrode terminals 71 are exposed at the second surface 41A of the second support member 40.

One external terminal 42 of the sub-module 20 is connected to one electrode terminal 71 of the chip component 70 with a wiring line 48, provided on the second surface 41A, interposed therebetween. The sub-module 20 is disposed between the antenna 50 and the chip component 70 in plan view. The second conductive film 43 is disposed on a partial region of the top surface 41T and substantially the entire region of the side surface 41S of the second support member 40 in and by which the sub-module 20, the antenna 50, and the chip component 70 are embedded and supported.

Next, effects of the ninth exemplary embodiment will be described.

In the ninth exemplary embodiment, the first conductive film 23 provided on the sub-module 20 and the second conductive film 43 provided on the second support member 40 function as electromagnetic shielding films. Therefore, the isolation between the sub-module 20, the antenna 50, and the chip component 70 in the antenna built-in RF front end portion 55 can be ensured. Furthermore, the isolation between the high frequency circuit in the antenna built-in RF front end portion 55 and the connector 85 can be ensured.

### Tenth Exemplary Embodiment

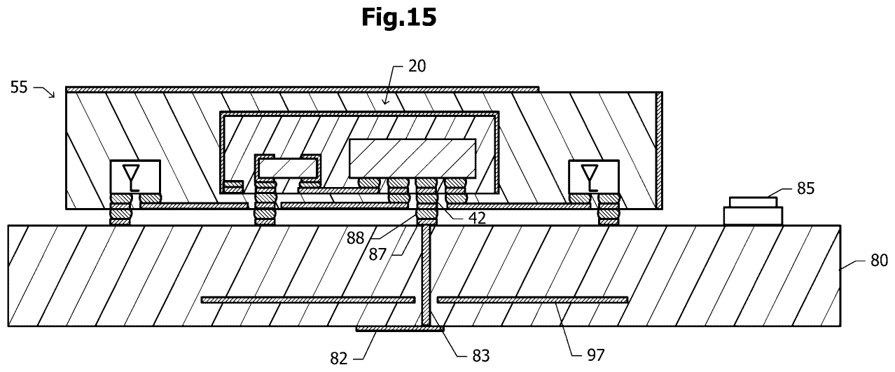

Next, an antenna module according to a tenth exemplary embodiment will be described with reference to FIG. 15. Hereinafter, the description of the configuration in common with the antenna module (FIG. 8) according to the sixth exemplary embodiment will be omitted.

FIG. 15 is a cross-sectional view of the antenna module according to the tenth exemplary embodiment. Similarly to the antenna module according to the sixth exemplary embodiment, the antenna module according to the tenth exemplary embodiment includes the antenna built-in RF front end portion 55 and the module substrate 80. In the tenth exemplary embodiment, an external radiating element 82 made of a metal pattern is disposed on the surface of the module substrate 80 opposite to the surface on which the antenna built-in RF front end portion 55 is mounted.

The external radiating element 82 is connected to the external terminal 42 of the antenna built-in RF front end portion 55 with a second feed line 83 disposed in the module substrate 80, the land 87, and the solder 88, interposed therebetween. The ground plane 97 is disposed in the module substrate 80. A patch antenna is configured by the external radiating element 82 and the ground plane 97.

Next, effects of the tenth exemplary embodiment will be described.

Similarly to the sixth exemplary embodiment, also in the tenth exemplary embodiment, it is possible to reduce the height and increase the bandwidth, and ensure the isolation between the high frequency circuit in the sub-module 20 and the antenna 50. Furthermore, in the tenth exemplary embodiment, the external radiating element 82 provided on the module substrate 80 can radiate radio waves in a direction opposite to the direction in which the surface of the module substrate 80, on which the antenna built-in RF front end portion 55 is mounted, faces.

### Eleventh Exemplary Embodiment

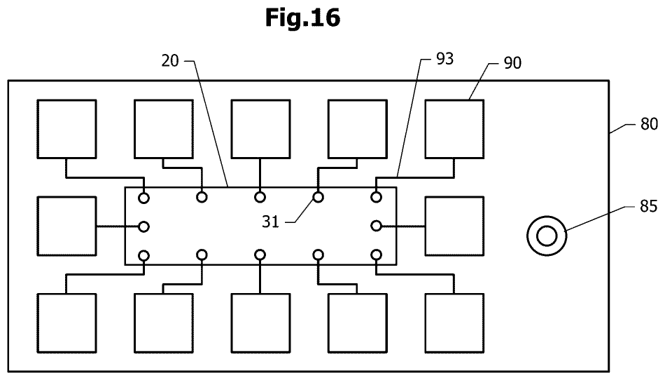

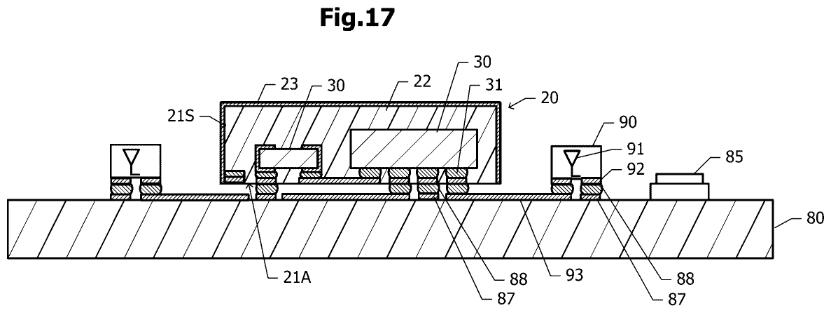

Next, an antenna module according to an eleventh exemplary embodiment will be described with reference to FIGS. 16 and 17. Hereinafter, the description of the configuration in common with the antenna module according to the first exemplary embodiment described with reference to the drawings of FIGS. 1 to 3C will be omitted.

FIG. 16 is a schematic view illustrating a planar positional relationship of a plurality of components of the antenna module according to the eleventh exemplary embodiment, and FIG. 17 is a cross-sectional view of the antenna module according to the eleventh exemplary embodiment. In the first exemplary embodiment (FIG. 1), the sub-module 20 is embedded in and supported by the second support member 40 (FIG. 1). On the other hand, in the eleventh exemplary embodiment, the sub-module 20 is not supported by the second support member 40, and is directly mounted on the module substrate 80 in a posture in which the first surface 21A is made to face the module substrate 80. Specifically, the internal terminal 31 of the sub-module 20 is fixed to the land 87 of the module substrate 80 by the solder 88.

The connector 85 and a plurality of external antennas 90 are mounted on the module substrate 80. The plurality of external antennas 90 are disposed to surround the sub-module 20 in plan view. Each of the external antennas 90 includes an external radiating element 91 and a plurality of antenna terminals 92. Each of the plurality of antenna terminals 92 is fixed to the land 87 of the module substrate 80 by the solder 88. Each one of the antenna terminals 92 of the external antennas 90 is connected to the internal terminal 31 of the sub-module 20 with a feed line 93, disposed on the module substrate 80, interposed therebetween.

Next, effects of the eleventh exemplary embodiment will be described.

In the eleventh exemplary embodiment, the sub-module 20 is mounted on the module substrate without using an interposer, so that the height can be reduced. Since the first conductive film 23 functions as an electromagnetic shielding film, the isolation between the high frequency circuit in the sub-module 20 and the external antenna 90 can be ensured. Furthermore, the first conductive film 23 disposed on the side surface 21S of the sub-module 20 functions as a reflector, so that the directivity of the external antenna 90 can be controlled.

### Twelfth Exemplary Embodiment

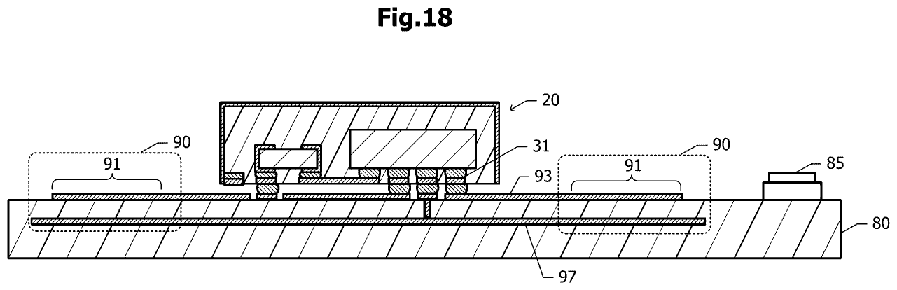

Next, an antenna module according to a twelfth exemplary embodiment will be described with reference to FIG. 18. Hereinafter, the description of the configuration in common with the antenna module (FIGS. 16 and 17) according to the eleventh exemplary embodiment will be omitted.

FIG. 18 is a cross-sectional view of the antenna module according to the twelfth exemplary embodiment. In the eleventh embodiment (FIG. 17), the external antenna 90 is surface-mounted on the module substrate 80. On the other hand, in the twelfth exemplary embodiment, the external antenna 90 is configured with a metal pattern disposed on or in the module substrate 80.

The external antenna 90 includes the external radiating element 91 disposed on the surface of the module substrate 80 on which the sub-module 20 is mounted and a portion of the ground plane 97 disposed on an inner layer of the module substrate 80. A patch antenna is configured by the external radiating element 91 and the ground plane 97. The external radiating element 91 is connected to the internal terminal 31 of the sub-module 20 with the feed line 93, disposed on the module substrate 80, interposed therebetween. The external antenna 90 radiates radio waves in a direction in which the surface of the module substrate 80, on which the sub-module 20 is mounted, faces.

Next, effects of the twelfth exemplary embodiment will be described.

Similarly to the eleventh exemplary embodiment, in the twelfth exemplary embodiment, it is possible to reduce the height, and it is possible to ensure the isolation between the high frequency circuit in the sub-module 20 and the external antenna 90. Furthermore, in the twelfth exemplary embodiment, since the external antenna 90 is configured with a metal pattern disposed on or in the module substrate 80, the number of components can be reduced as compared with a configuration in which a surface-mounted external antenna is mounted.

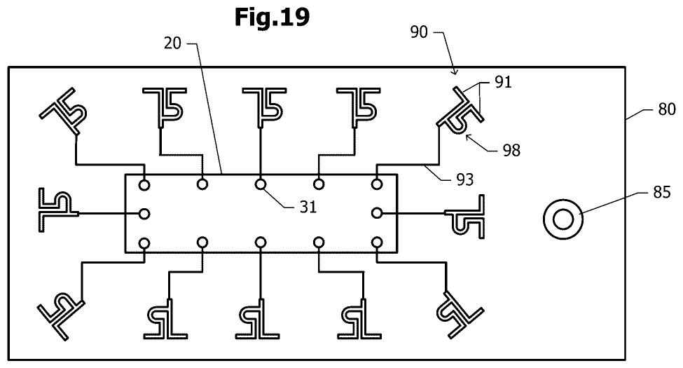

Next, an antenna module according to a modification example of the twelfth exemplary embodiment will be described with reference to FIG. 19.

FIG. 19 is a schematic view illustrating a planar disposition of a plurality of components of the antenna module according to the modification example of the twelfth exemplary embodiment. In the twelfth exemplary embodiment (FIG. 18), a patch antenna is used as the external antenna 90. On the other hand, in the present modification example, a dipole antenna is used as the external antenna 90. The external radiating element 91 of the external antenna 90 includes two radiating elements constituting the dipole antenna. The external radiating element 91 is connected to the feed line 93 with a balun 98 interposed therebetween. Furthermore, the feed line 93 is connected to the internal terminal 31 of the sub-module 20. A differential line may be used as the feed line 93, and the differential line may be connected to the two radiating elements constituting the dipole antenna without using the balun 98. As in the present modification example, the dipole antenna may be used as the external antenna 90.

### Thirteenth Exemplary Embodiment

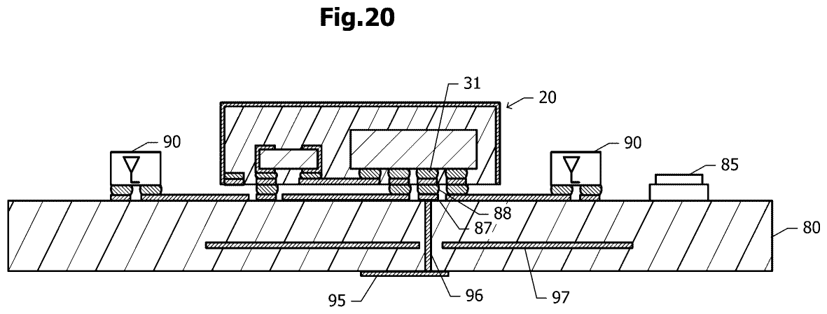

Next, an antenna module according to a thirteenth exemplary embodiment will be described with reference to FIG. 20. Hereinafter, the description of the configuration in common with the antenna module (FIGS. 16 and 17) according to the eleventh exemplary embodiment will be omitted.

FIG. 20 is a cross-sectional view of the antenna module according to the thirteenth exemplary embodiment. In addition to the configuration of the antenna module (FIG. 17) according to the eleventh exemplary embodiment, the thirteenth exemplary embodiment includes an external radiating element 95 made of a metal pattern disposed on a surface opposite to the surface of the module substrate 80 on which the sub-module 20 is mounted. The external radiating element 95 is connected to the internal terminal 31 of the sub-module 20 with the feed line 96 disposed in the module substrate 80, the land 87, and the solder 88, interposed therebetween. The ground plane 97 is disposed in the module substrate 80, and a patch antenna is configured by the external radiating element 95 and the ground plane 97.

Next, effects of the thirteenth exemplary embodiment will be described.

Similarly to the eleventh exemplary embodiment, in the thirteenth exemplary embodiment, the height can be reduced. Furthermore, by disposing the external radiating element 95, radio waves can be radiated in a direction opposite to the direction in which the surface of the module substrate 80, on which the sub-module 20 is mounted, faces.

### Fourteenth Exemplary Embodiment

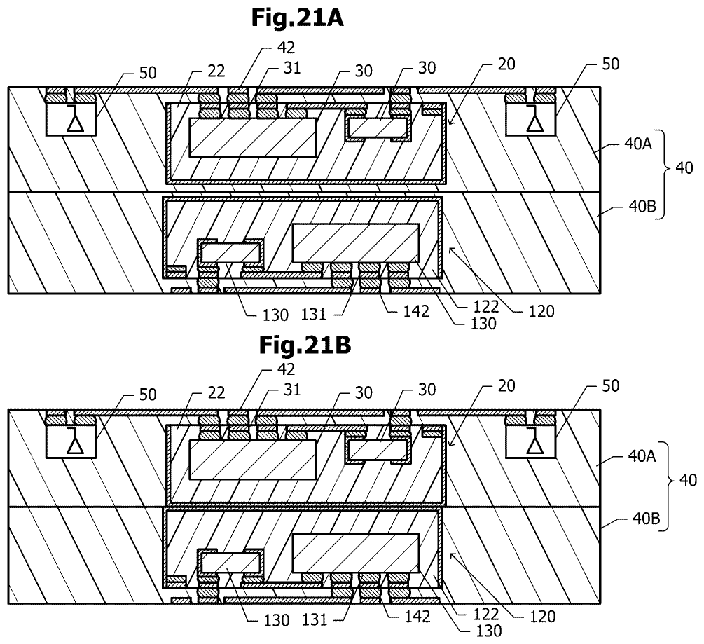

Next, an antenna module according to a fourteenth exemplary embodiment will be described with reference to FIG. 21A. Hereinafter, the description of the configuration in common with the antenna module according to the first exemplary embodiment described with reference to the drawings of FIGS. 1 to 3C will be omitted.

FIG. 21A is a cross-sectional view of the antenna module according to the fourteenth exemplary embodiment. The second support member 40 is divided into a first part 40A and a second part 40B. The sub-module 20 and the antenna 50 are supported by the first part 40A. The plurality of external terminals 42 are exposed at one surface of the first part 40A. The configurations of the sub-module 20, the antenna 50, the plurality of external terminals 42, and the first part 40A of the second support member 40 are the same as the configuration of the first embodiment (FIG. 1).

A second sub-module 120 is covered with and supported by the second part 40B of the second support member 40. To be distinguished from the second sub-module 120, the sub-module 20 supported by the first part 40A may be referred to as a first sub-module 20. The second sub-module 120 includes a plurality of second electronic components 130, a plurality of second internal terminals 131, and a third support member 122. The configurations of these are the same as the configurations of the plurality of electronic components 30, the plurality of internal terminals 31, and the first support member 22 of the first sub-module 20.

The second sub-module 120 is covered with and supported by the second part 40B of the second support member 40. A plurality of second external terminals 142 are exposed at the surface of the second support member 40 opposite to the surface at which the plurality of external terminals 42 are exposed. The plurality of second external terminals 142 are connected to the plurality of second internal terminals 131. The surface of the first part 40A opposite to the surface at which the plurality of external terminals 42 are exposed and the surface of the second part 40B opposite to the surface at which the plurality of second external terminals 142 are exposed is bonded to each other.

The surface (hereinafter, referred to as a top surface) of the first sub-module 20, which faces in the opposite direction to the surface of the second support member 40 at which the plurality of external terminals 42 are exposed, faces the surface (hereinafter, referred to as a top surface) of the second sub-module 120, which faces in the same direction as the surface of the second support member 40 at which the plurality of external terminal 42 are exposed, with the second support member 40 interposed therebetween.

Next, a method for manufacturing an antenna module according to a fourteenth exemplary embodiment will be described. A structure at the manufacturing stage, illustrated in FIG. 3C, of the antenna module according to the first exemplary embodiment is fabricated. Through the steps so far, the first part 40A of the second support member 40 and the plurality of first sub-modules 20 supported by the first part 40A are fabricated. Similarly, the second part 40B of the second support member 40 and the plurality of second sub-modules 120 supported by the second part 40B are fabricated.

By bonding the first part 40A to the second part 40B and removing the temporary substrate 101, the antenna module according to the fourteenth exemplary embodiment can be fabricated.

Next, an antenna module according to a modification example of the fourteenth exemplary embodiment will be described with reference to FIG. 21B. FIG. 21B is a cross-sectional view of the antenna module according to the modification example of the fourteenth exemplary embodiment. In the fourteenth exemplary embodiment (FIG. 21A), the top surface of the first sub-module 20 and the top surface of the second sub-module 120 face each other with the second support member 40 interposed therebetween. On the other hand, in the modification example illustrated in FIG. 21B, the top surface of the first sub-module 20 and the top surface of the second sub-module 120 face each other without the second support member 40 interposed therebetween. For example, between the top surface of the first sub-module 20 and the top surface of the second sub-module 120 is disposed an adhesive layer (not illustrated) for bonding both.

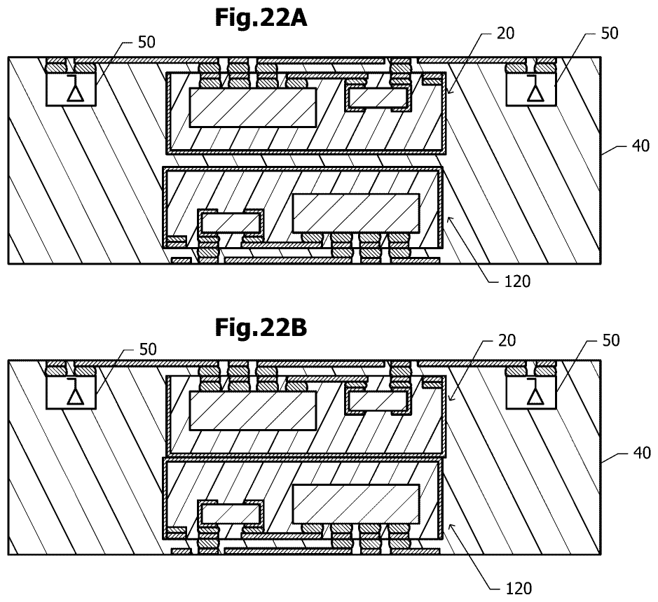

Next, an antenna module according to other modification examples of the fourteenth exemplary embodiment will be described with reference to FIGS. 22A and 22B. FIGS. 22A and 22B are cross-sectional views of the antenna module according to the other modification examples of the fourteenth exemplary embodiment. In the antenna modules according to the fourteenth exemplary embodiment (FIG. 21A) and the modification example (FIG. 21B) of the fourteenth exemplary embodiment, the second support member 40 includes the first part 40A and the second part 40B, and both are bonded to each other. On the other hand, in the modification examples illustrated in FIGS. 22A and 22B, the first sub-module 20, the antenna 50, and the second sub-module 120 are supported by a single integrated second support member 40.

In the modification example illustrated in FIG. 22A, the top surface of the first sub-module 20 faces the top surface of the second sub-module 120 with the second support member 40 interposed therebetween. In the modification example illustrated in FIG. 22B, the top surface of the first sub-module 20 faces the top surface of the second sub-module 120 without the second support member 40 interposed therebetween. For example, the top surface of the first sub-module 20 is in contact with the top surface of the second sub-module 120.

Next, a method for manufacturing the antenna module illustrated in FIG. 22A will be described. First, a structure at the manufacturing stage, illustrated in FIG. 3B, of the antenna module according to the first exemplary embodiment is fabricated. A structure including the second sub-module 120 is similarly fabricated. The two temporary substrates 101 are disposed so that the surface on which the first sub-module 20 is mounted and the surface on which the second sub-module 120 is mounted face each other, and a space between the two temporary substrates 101 is filled with a liquid resin by using a transfer molding method. By solidifying the liquid resin, the antenna module illustrated in FIG. 22A is completed.

In the antenna module according to the modification example illustrated in FIG. 22B, it is sufficient that the top surface of the first sub-module 20 and the top surface of the second sub-module 120 are brought into contact with each other with the two temporary substrates 101 facing each other.

Next, effects of the fourteenth exemplary embodiment and the modification example thereof will be described.

Similarly to the first exemplary embodiment, also in the fourteenth exemplary embodiment and the modification examples thereof, it is possible to reduce the height of the antenna module, to improve the isolation between the first sub-module 20 and the antenna 50, and to increase the bandwidth of the antenna 50. Furthermore, in the fourteenth exemplary embodiment and the modification examples thereof, the first sub-module 20 and the second sub-module 120 are disposed in a stacked manner, so that high-density mounting is possible.

Each of the above-described exemplary embodiments is an example, and it goes without saying that partial replacement or combination of configurations illustrated in different exemplary embodiments is possible. The same operation and effect due to the same configuration of a plurality of exemplary embodiments will not be sequentially referred to for each exemplary embodiment. Furthermore, the present disclosure is not limited to the above-described exemplary embodiments. For example, a person skilled in the art will recognize that various changes, improvements, combinations, and the like of the described exemplary embodiments are possible without departing from the scope of the present disclosure.

What is claimed is:

1. An antenna module comprising:
a sub-module including
a plurality of electronic components, each including a plurality of internal terminals,
a first support that covers and supports the plurality of electronic components to expose the plurality of internal terminals, and
a first conductive film that is disposed on at least a part of the first support;
at least one antenna;
a second support that supports the sub-module and supports the antenna; and
a plurality of external terminals that are connected to the plurality of internal terminals and are exposed from the second support.

2. The antenna module according to claim 1,
wherein the plurality of internal terminals are exposed at a first surface of the first support, the plurality of external terminals are exposed at a second surface of the second support, and the first surface and the second surface face in a same direction.

3. The antenna module according to claim 2,
wherein the antenna is configured by an antenna component including a radiating element and an antenna terminal, and
the antenna component is covered with and supported by the second support to expose the antenna terminal at the second surface.

4. The antenna module according to claim 3,
wherein the second support includes a top surface that faces in a direction opposite to the second surface, and
the antenna module further comprises a second conductive film disposed on the top surface.

5. The antenna module according to claim 4,
wherein the second conductive film is disposed in a partial region of the top surface, and a region in which the second support is exposed from the second conductive film and at least one of the antenna components overlap in plan view.

6. The antenna module according to claim 3, further comprising:
a first feed line that is disposed on the second surface and connects one of the plurality of external terminals to the antenna; and
a ground plane that is disposed in a region of the second surface that does not overlap the first feed line.

7. The antenna module according to claim 3, further comprising:
a surface-mounted chip component that is supported by the second support and includes an electrode terminal exposed at the second surface,
wherein when the second surface is viewed in plan, the sub-module is disposed between the antenna component and the chip component.

8. The antenna module according to claim 2,
wherein the antenna includes a radiating element configured with a metal pattern disposed on the second surface.

9. The antenna module according to claim 2,
wherein the second support includes a top surface that faces in a direction opposite to the second surface, and a side surface that connects the top surface to the second surface, and
the antenna includes a radiating element configured with a metal pattern disposed on the side surface.

10. The antenna module according to claim 2, further comprising:
a module substrate on which the second support that supports the sub-module and the antenna is mounted;
a connector that is mounted on a same surface as a surface of the module substrate on which the second support is mounted; and
a third conductive film that is disposed in a region of a surface of the second support, the surface facing a side of the connector.

11. The antenna module according to claim 10, further comprising:
an external antenna component that is mounted on the same surface as the surface of the module substrate on which the second support is mounted,
wherein the third conductive film is disposed in a region of the surface of the second support, the surface facing the external antenna component.

12. The antenna module according to claim 2, further comprising:
a module substrate on which the second support that supports the sub-module and the antenna is mounted;
an external radiating element configured with a metal pattern disposed on the module substrate; and
a second feed line that is disposed in the module substrate and connects one of the plurality of external terminals to the external radiating element.

13. The antenna module according to claim 1, further comprising:
a second sub-module including a plurality of second electronic components each including a plurality of second internal terminals, and a third support that covers and supports the plurality of second electronic components to expose the plurality of second internal terminals; and
a plurality of second external terminals that are exposed at a surface of the second support opposite to a surface at which the plurality of external terminals are exposed,
wherein the second sub-module is covered with and supported by the second support, and
the plurality of second internal terminals are connected to the plurality of second external terminals.

14. The antenna module according to claim 13,
wherein a surface of the sub-module, which faces in a direction opposite to the surface of the second support at which the plurality of external terminals are exposed, faces a surface of the second sub-module, which faces in a same direction as the surface of the second support at which the plurality of external terminals are exposed, without the second support interposed therebetween.

15. The antenna module according to claim 13,
wherein the second support includes a first part that supports the sub-module and the antenna, and a second part that supports the second sub-module, and the first part is bonded to the second part.

16. An antenna module comprising:
a sub-module including
a plurality of electronic components each including a plurality of internal terminals,
a first support that covers and supports the plurality of electronic components to expose the plurality of internal terminals, and
a first conductive film that is disposed on at least a part of the first support;
a module substrate on which the sub-module is mounted;
a first antenna that is provided on the module substrate; and
a second antenna that is provided on a surface of the module substrate opposite to the first antenna,
wherein the first antenna includes a radiating element made of a metal pattern, and
the second antenna is surface-mounted on the module substrate.

17. The antenna module according to claim 16,
wherein the first antenna is provided on a surface of the module substrate opposite to a surface on which the sub-module is mounted.

18. The antenna module according to claim 16, further comprising:
a feed line that is disposed in the module substrate and connects one of the plurality of internal terminals of the sub-module to the antenna.

19. The antenna module according to claim 8,
wherein the second support includes a top surface that faces in a direction opposite to the second surface, and a side surface that connects the top surface to the second surface, and
the antenna includes a radiating element configured with a metal pattern disposed on the side surface.

20. The antenna module according to claim 14,
wherein the second support includes a first part that supports the sub-module and the antenna, and a second part that supports the second sub-module, and the first part is bonded to the second part.
